(19) United States
(12) Patent Application Publication
(10) Pub. No.: US 2026/0105958 A1
(43) Pub. Date: Apr. 16, 2026

(54) MEMORY DEVICE

(71) Applicant: THE UNIVERSITY COURT OF THE UNIVERSITY OF EDINBURGH, Edinburgh (GB)

(72) Inventors: Alexantrou SERB, Edinburgh (GB); Sachin MAHESHWARI, Edinburgh (GB); Themistoklis PRODROMAKIS, Edinburgh (GB); Mohammed MUGHAL, Glasgow (GB); Adrian WHEELDON, Edinburgh (GB); Yihan PAN, Edinburgh (GB); Shady Onsey Haleem RIZKALLA, Edinburgh (GB)

(21) Appl. No.: 19/115,340

(22) PCT Filed: Dec. 14, 2023
(86) PCT No.: PCT/GB2023/053243

§ 371 Date: Mar. 26, 2025

(30) Foreign Application Priority Data
Dec. 19, 2022 (GR) 20220101056
Jan. 31, 2023 (GB) 2301357.6

(51) Int. Cl. G11C 15/04; G11C 13/00

(52) U.S. Cl. CPC G11C 15/043; G11C 13/0038; G11C 13/004; G11C 13/0069

(57) ABSTRACT

A memory device for storing data comprising: voltage divider circuitry comprising at least one memory element, wherein the at least one memory element is operable or selected to be in a resistance and/or impedance state representative of at least part of the data, wherein the voltage divider circuitry is configured to divide a voltage in dependence on the resistance and/or impedance state of the at least one memory element as part of a data read and/or a data write operation, wherein the at least one memory element is capacitive and is connected to one or more further capacitive elements such that the voltage divider circuitry comprises a capacitor divider arrangement.

### FIELD

The present invention relates to a memory device or system, for example, a memory device or system for performing a content addressable read operation.

### BACKGROUND

Memory structures such as SRAM and DRAM are address-addressable only. With the development of more intelligent systems, address-addressable-only memories may limit computing efficiency in terms of data processing and transferring. Advanced intelligent systems require not only memory storage, but also the ability to locate memory addresses by certain content. Such memory is referred to as content addressable memory (CAM) or associative memory.

Known CAMs using CMOS technology typically use SRAM as their memory elements to store data and its data comparison is implemented by NAND-based or NOR-based topologies. Although a CAM memory is desired because of its high operational speed and searching function, its density may increase its cost of implementation more than the other standard memories in CMOS.

Alternatives to CMOS technologies include, for example, Resistive Random Access Memory (RRAM), Phase Change Memory (PCM), Ferroelectric RAM (FeRAM), and magnetic RAM (MRAM).

### SUMMARY

In accordance with a first aspect, there is provided, a memory device for storing data comprising: voltage divider circuitry comprising at least one memory element, wherein the at least one memory element is operable or selected to be in a resistance and/or impedance state representative of at least part of the data, wherein the voltage divider circuitry is configured to divide a voltage in dependence on the resistance and/or impedance state of the at least one memory element. The voltage may be divided as part of a data read and/or a data write operation.

The at least one memory element may be capacitive. The at least one memory element may be connected to one or more further capacitive elements such that the voltage divider circuitry comprises a capacitor divider arrangement. The capacitor divider arrangement may be referred to as a capacitive voltage divider arrangement and may comprise a capacitive voltage divider. The at least one memory element may comprise a capacitive component. The at least one memory element may comprise a parasitic capacitance.

The voltage divider circuitry may be configured to avoid and/or at least reduce resistive paths during the data read and/or data write operation of the at least one variable resistance memory element.

The voltage divider circuitry may comprise a voltage divider.

The at least one memory element may be operable to be in a high or a low resistance and/or impedance state. The voltage divider circuitry may be configured to at least reduce the voltage shared with the least one memory element of the voltage divider circuitry when the at least one memory element is in a low resistance and/or impedance state.

The memory device according to any preceding claim wherein the voltage divider circuitry is configured to share the voltage between the at least one memory element and the one or more further elements when the at least one memory element is in a high resistance and/or impedance state.

The one or more impedance states may comprise a combination of at least resistance and/or reactance. The one or more impedance states may comprise one or more resistance states. The one or more impedance states may comprises one or more reactance states. The one or more impedance states may comprises a combination of resistance and reactance states.

The sharing of the voltage may be further in dependence on the input voltages and the values of capacitance and reactance of the at least one memory element and the one or more further elements. The voltage divider circuitry may comprise the at least one memory element connected to one or more further elements in a voltage divider arrangement such that the voltage is divided between at least one memory element and the one or more further elements. The at least one memory element and/or the one or more further elements provide a capacitance and/or an inductance and/or a reactance.

The voltage divider circuitry may be configured to operate as a capacitance divider when the at least one memory element is in a high resistance and/or high impedance state.

The parasitic capacitance of the memory element may provide part of the capacitance of the capacitance divider circuitry. The parasitic capacitance of one further element may provide part of the capacitance of the capacitance divider.

The at least one memory element may be configured to substantially block and/or permit a current flow through the at least one memory element in dependence on the resistance and/or impedance of the memory element.

The voltage divider circuitry may comprise the at least one memory element connected to one or more further elements wherein the voltage divider circuitry is connected between a first data line and a second data line. The voltage divider circuitry may further comprise: one or more output transistors connected between the at least one memory element and the one or more further elements, optionally to a common node between the at least one memory element and the one or more further elements, such that a divided voltage is provided to the gate electrode of the at least one output transistor; wherein the at least one output transistor is coupled to a matchline thereby to control the matchline in dependence on the divided voltage.

The at least one memory element may be a capacitive component. The one or more further elements may comprise a further capacitor.

The at least one output transistor may comprise a threshold voltage such that the matchline is switched in dependence on whether the data represented by the first data line and the second data line matches the data stored in the memory element.

The device may further comprises at least one write transistors connected between the at least one memory elements and the one or more further elements, wherein the at least one write transistor is operable to apply a voltage to the at least one memory element thereby to write data to the at least one memory element. The at least one write transistor may be connected at its drain electrode to the common node.

The memory device may further comprise at least one further transistor operable to enable reading of data from the at least one memory element and/or forming part of a read out transistor arrangement. The at least one further transistor may be operable to enable reading of data from the at least one memory element as part of a content addressable read operation.

The voltage divider circuitry may be coupled to one or more, optionally two, search lines for providing an input voltage representative of query data. The voltage divider circuitry may be configured to output a voltage representing a match and/or a mismatch between the stored data and the query data. The search lines may also be referred to as data lines.

The memory device may be configured to perform a content addressable search process. The memory device may be configured to divide a voltage as part of a content addressable read operation. The read operation may comprise a content addressable read operation and may form part of a content addressable search.

The voltage divider circuitry may be further configured to receive one or more signals representative of search data and output a signal representing a match and/or a mismatch between the stored data and the search data.

The device may further comprise read circuitry for performing the data read operation, wherein the data read operation comprises receiving an output voltage from the voltage divider circuitry, wherein the output voltage is dependent on at least the resistance state and/or the impedance state of the memory element.

The read circuitry may comprise at least one output transistor driven by the output voltage of the voltage divider circuitry.

The device may further comprise write circuitry for applying a voltage to the at least one memory state thereby to set the resistance state and/or impedance state of the at least one memory element.

The write circuitry may comprise at least one write transistor coupled to the voltage divider circuitry.

The at least one memory element may be selected to be in or is operable to be in one of a plurality of resistance and/or impedance states.

The at least one memory element may comprise a variable resistance and/or variable impedance memory element operable to be in one of two or more resistance and/or impedance states.

The at least one memory element may comprise a memory element with a resistance and/or impedance selected corresponding to a resistance state.

The plurality of resistance states may comprise a high resistance state and a low resistance state. The low resistance state may correspond to a resistance in a range 100 to 1000 Ohms, optionally 0 to 1000 Ohms. The high resistance state may correspond to a resistance above 10 MOhms. The high resistance state may correspond to a resistance such that, in the high resistance state, the voltage divider circuitry operates as a voltage divider. The low resistance state may correspond to a resistance such the voltage divider circuitry does not operate as a voltage divider. The lower resistance state may correspond to a resistance such that the voltage divider bypasses one or more elements in the voltage divider, for example, the at least one memory element. The low resistance state may correspond to a resistance such that the voltage divider circuitry divides the voltage between at least one fewer element than the high resistance state.

The at least one memory element and, optionally, the one or more further elements may comprise a non-zero reactance. The at least one memory element may comprise a variable reactance.

The at least one memory element may be configured to retain the resistance and/or impedance state in the absence of power.

The at least one memory element may be operable to be in at least a first resistance and/or impedance state or a second resistance and/or impedance state thereby to represent a binary data bit and/or binary values.

The at least one memory element may comprise a memristor, a RRAM element, a memcapacitor, a phase change material (PCM) device, a magnetic tunnel junction (MTJ), a programmable resistor, a non-volatile switch, a floating gate MOSFET.

The memory device may form part of a bit cell or memory cell.

The voltage divider circuitry may be operable in one or more modes comprising at least: a content addressable read mode, an address addressable read mode and a write operation mode.

The memory device may comprise controlling circuitry configured to select the operational mode of the memory device.

The memory device may comprise a non-volatile memory device.

The memory device may comprise a bit cell. The memory device may comprise a memory cell. The memory device may be array-able.

The at least one memory element may comprise one of: a memristor device, a RRAM device, a memcapacitor device, a phase change material (PCM) device, a magnetic tunnel junction (MTJ) device, a programmable resistor device, a non-volatile switch device, a floating gate MOSFET device.

The at least one memory element may comprise or form part of an at least one memory device operable and/or selected to be in a resistance and/or impedance state representative of at least part of the data.

In accordance with a further aspect, there is provided a memory system comprising a plurality of memory cells, wherein each memory cell comprises:
voltage divider circuitry comprising at least one memory element, wherein the at least one memory element is operable or selected to be in a resistance and/or impedance state representative of at least part of the data;
wherein the voltage divider circuitry is configured to divide a voltage in dependence on the resistance and/or impedance state of the at least one memory element as part of a data read and/or a data write operation. The memory system may comprise one or more common, or shared, readout and/or write lines for one or more groups of the plurality of memory cells.

The plurality of memory cells may be arranged in an array. The memory cells may be grouped in rows or columns of the array.

In accordance with a further aspect, there is provided a method of performing a data read and/or a data write operation using a memory device, wherein the memory device comprises voltage divider circuitry comprising at least one memory element, wherein the at least one memory element is operable or selected to be in a resistance and/or impedance state representative of at least part of the data, providing a memory device voltage divider circuitry;
wherein the method comprising dividing a voltage applied to the voltage divider circuitry in dependence on the resistance and/or impedance as part of a data read and/or data write operation.

The method may further comprise performing a data read and/or data write operation. The method may further comprise operating the at least one memory element to place the at least one memory element in a resistance and/or impedance state representative of the data.

Features of any one aspect may be applied as features of any other aspect of the invention, as appropriate. For example, method features may be applied as system or device features and vice versa. In addition, device features may be applied as system features and vice versa.

### BRIEF DESCRIPTION

Various aspects of the invention will now be described by way of example only, and with reference to the accompanying drawings, of which:

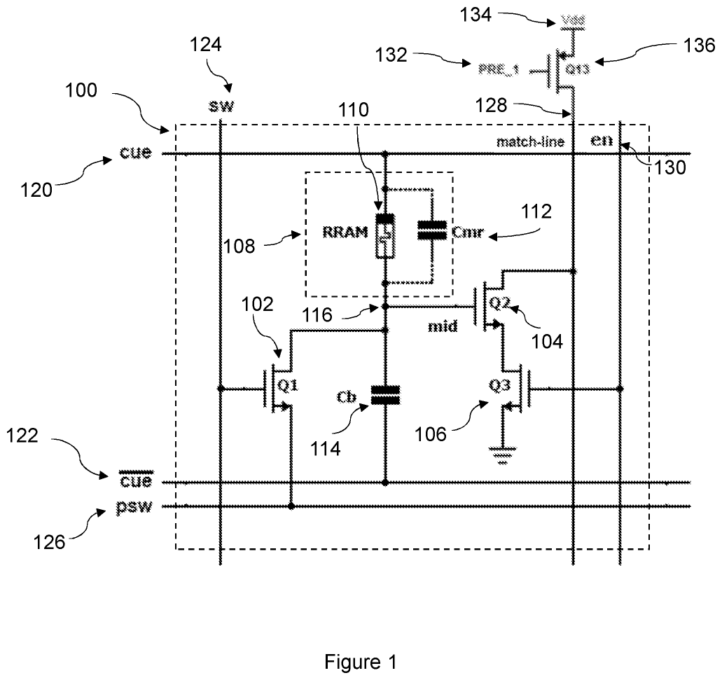

FIG. 1 is a circuit diagram of a memory cell, in accordance with an embodiment;

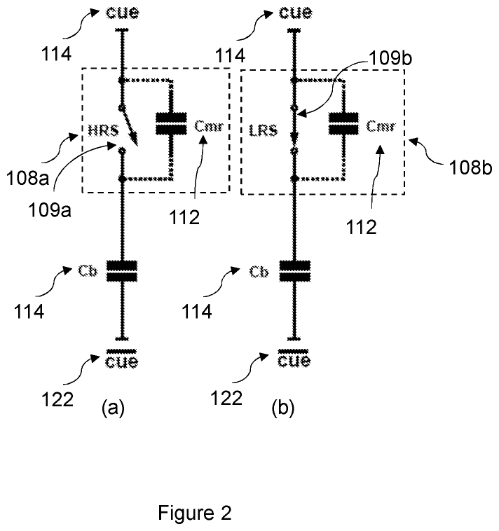

FIG. 2(a) is a circuit diagram of a first equivalent circuit of the memory cell and FIG. 2(b) is a circuit diagram of a second equivalent circuit of the memory cell;

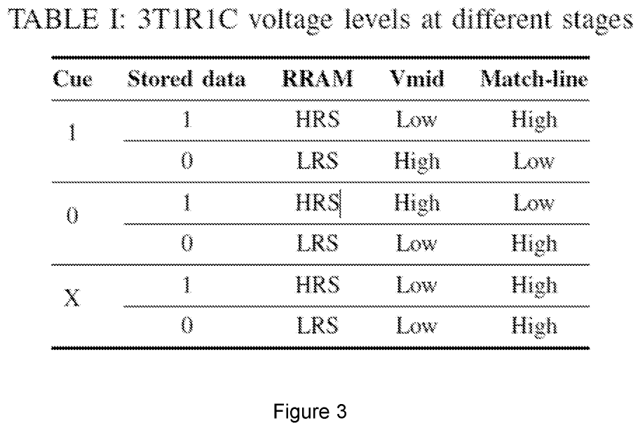

FIG. 3 is a table illustrating voltage levels in the circuit at different stages of a content addressable read operation;

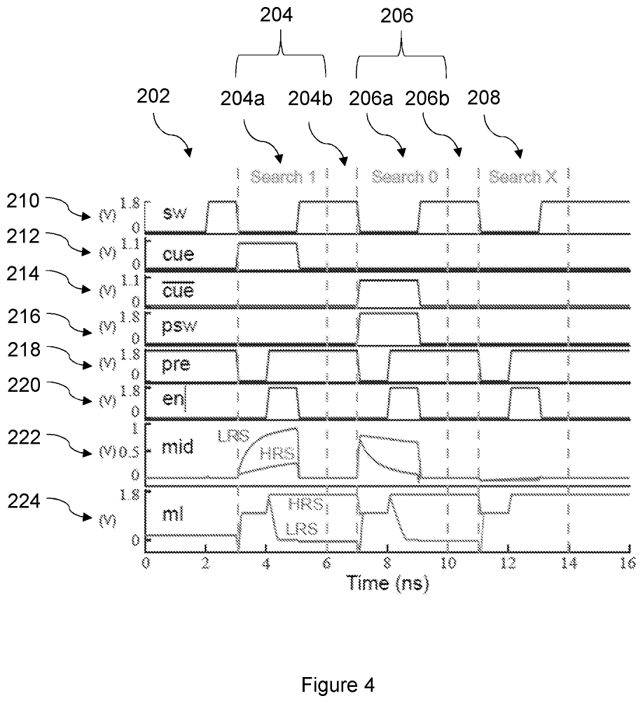

FIG. 4 is a timing diagram for a content addressable read operation;

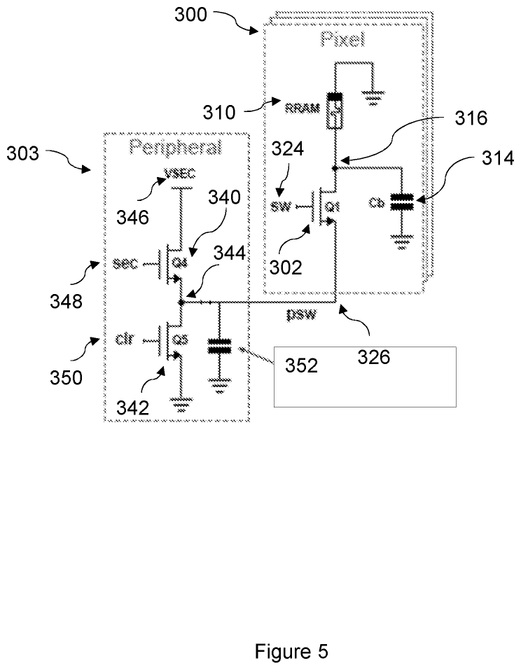

FIG. 5 is a circuit diagram depicting an equivalent circuit for the memory cell for an address addressable read operation;

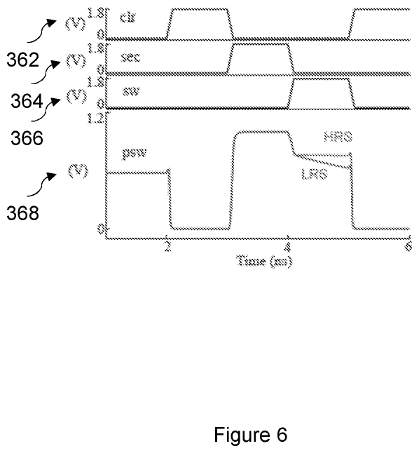

FIG. 6 is a timing diagram for an address addressable read operation;

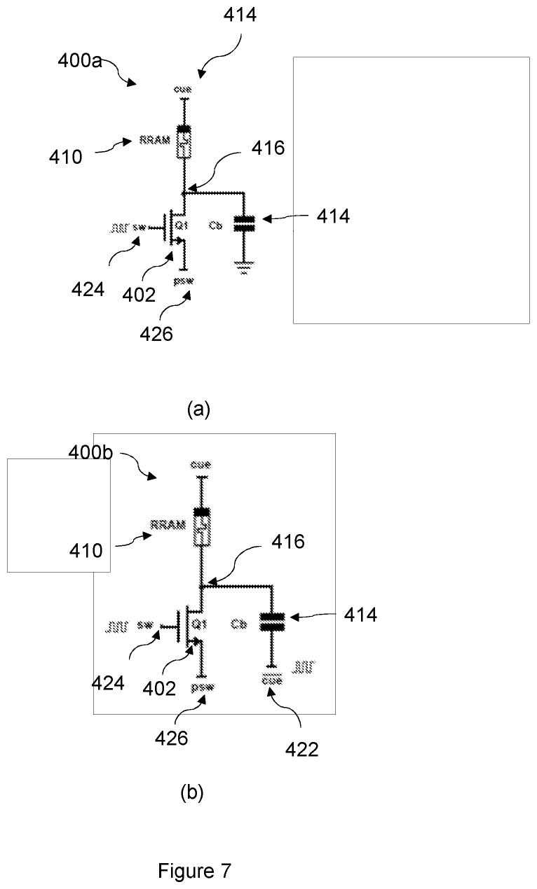

FIG. 7(a) is a first circuit diagram depicting a first equivalent circuit for the memory cell for a write operation and FIG. 7(b) is a second circuit diagram depicting a second equivalent circuit for the memory cell for a write operation and FIG. 7(c) is a timing diagram for a write operation;

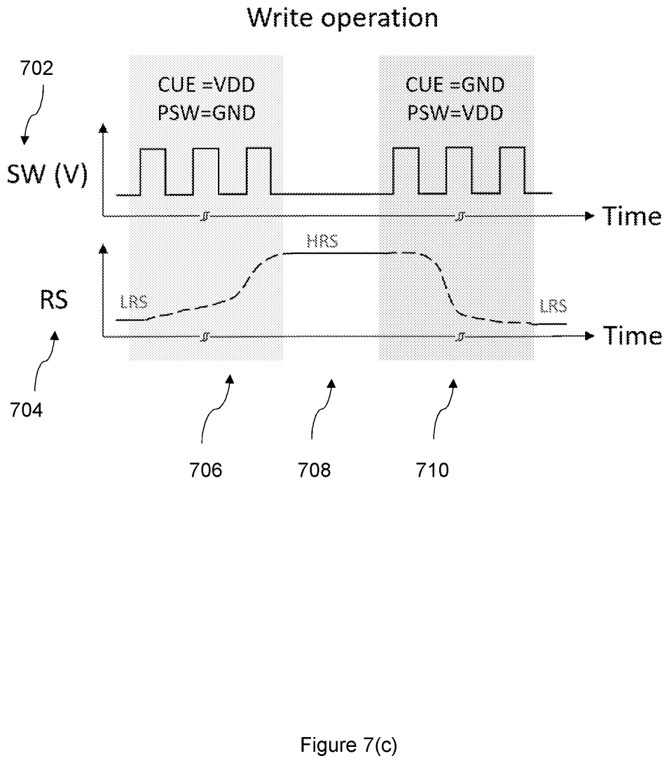

FIG. 8(a) is a cross-sectional view of a RRAM device, in accordance with an embodiment and FIG. 8(b) is a top down view of the RRAM device;

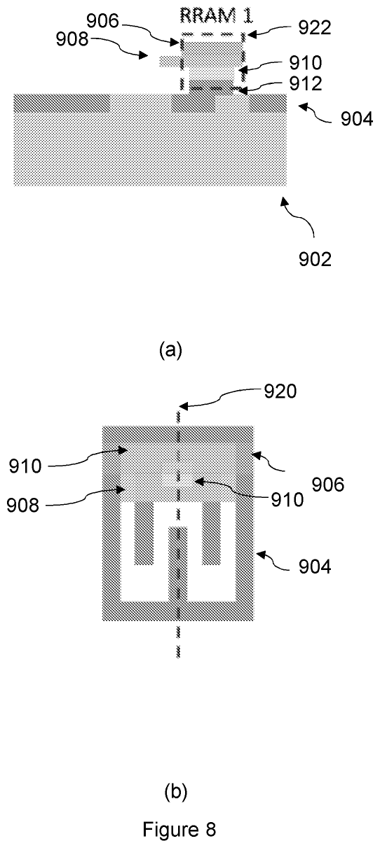

FIG. 9 is a schematic diagram of a memory device having an array of memory cells, in accordance with an embodiment;

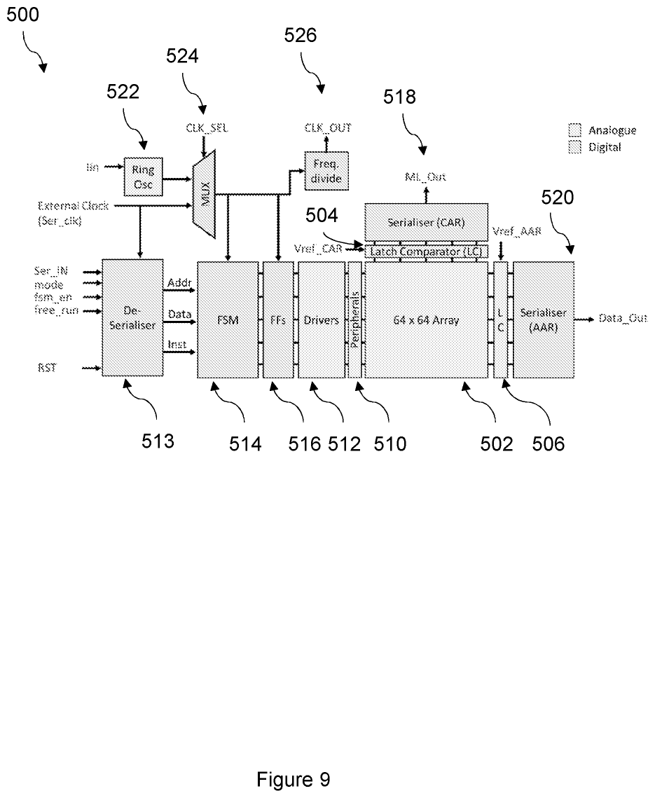

FIG. 10 is a circuit diagram of a memory cell, in accordance with a further embodiment, and

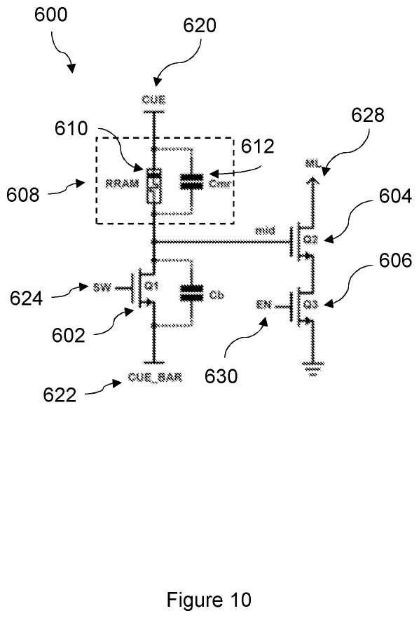

FIG. 11 is a circuit diagram of a memory cell, in accordance with a further embodiment, operating in a DRAM mode.

### DETAILED DESCRIPTION

FIG. 1 is a circuit diagram of part of a memory device, in particular, a memory cell 100. An embodiment of a memory device having a plurality of memory cells as described with reference to FIGS. 1 to 7, in an array arrangement, together with associated circuitries including input and output circuitries is described with reference to FIG. 9. The memory cell may alternatively be referred to as a memory pixel. It will be understood that the memory cell may array-able and provided together with a plurality of other memory cells. The memory device depicted in FIG. 1 is a capacitive-based RRAM memory capable of performing content addressable read operations. As described in the following, the memory has a RRAM element with configurable resistance states that can be selected to be at different levels. As described in the following, the Metal-Insulator-Metal (MIM) structure of RRAM changes its resistance by redox processes, coupling to ion-migration effects. The RRAM resistance can therefore be switched to a low resistance state (LRS) or a high resistance state (HRS) by applying set and reset threshold pulses respectively. The content addressable memory described in the following may reduce or avoid use of DC resistance paths and therefore may provide improved power efficiency solutions with a high throughput rate at low cost and high reliability for CAM designs. While a number of the following embodiments relate to a memory cell have RRAM elements, it will be understood that other types of memory elements may be used, as described in further detail in the following.

FIG. 1 depicts memory cell 100 in accordance with an embodiment. For the purposes of the following description, memory cell 100 is depicted together with additional components for controlling the voltage of an output of the memory cell, in particular, for controlling the voltage of a matchline. In some embodiments, these additional components are considered to be part of the memory cell 100. The memory cell also has associated supply voltage circuitry that is not depicted in FIG. 1.

The memory cell 100 describe in the following is configured to be operated in a number of different modes: content addressable read mode, address addressable read mode and write mode. Content addressable read mode is described with reference to FIGS. 1 to 4; address addressable read mode is described with reference to FIGS. 5 and 6; and the write mode is described with reference to FIG. 7. It will be understood that, in some embodiments, the memory cell 100 has controlling circuitry and/or is provided together with associated controlling circuitry for selecting the operational mode of the memory cell. A content addressable read operation may be performed as part of a content addressable search process.

The memory cell 100 is a 3T1C 1R memory cell characterised by having three transistors, one capacitor and an RRAM element. In further detail, the memory cell has a write transistor 102 (also referred to as a special resistor or simply as Q1), an output transistor 104 (also referred to as Q2) and a further transistor 106 (also referred to as further transistor or, for brevity, as Q3). The write transistor 102 may be operable to enable writing of data to the memory element 108. The further transistor 106 may be further operable as part of a read-out transistor arrangement. The further transistor may be referred to as a read-enable transistor, for example, during a content addressable read operation. For example, the output transistor 104 and further transistor 106 together operate as a read-out transistor arrangement and may also be referred to as output transistors. In further embodiments, the two transistors Q2 and Q3 are replaced by a single device with two gates. Depending on the operational of the device, it will be understood that the output transistor and/or further transistor forms part of a read circuitry for performing a date read operation.

In the present embodiment these three transistors are nMOS transistors are used to allow cell density in an array arrangement to be maximised. Each nMOS transistor has a gate electrode, a drain electrode and a source electrode and is operable such that, when the nMOS transitory receives a non-negligible voltage at the gate, current flows between the source to the drain and, such that, when the nMOS transistor receives a zero voltage at the gate, substantially no current flows between the source and the drain. In the following Figures, the arrow of the transistor indicates the source electrode. The transistor Q1 is reused for both write and address addressable read operations, while transistors Q2 and Q3 are activated for CAR. Suitable control circuitry may be provided for activating certain components in the memory cell depending on the mode of operation.

The memory cell 100 has a variable resistance element 108. In the present embodiment, the variable resistance element 108 is a RRAM 110. The RRAM 110 has a capacitance. The dotted capacitance Cₘᵣ 112 represents the parasitic capacitance introduced by the RRAM MIM structure the size of which is determined by the area of the structure of the fabricated RRAM. The parasitic capacitance also depends on the distance between the metal plates, corresponding, in the present embodiment, to the thickness of the insulating layer. The metal plates are formed by metal electrodes/lines arranged on the chip. It will be understood that, for example, the cue line, has a physical length, width and height and there will be a cross-coupling parasitic capacitance between it and, for example, the matchline since they cross each other (albeit at different heights inside the chip). The structure of the RRAM is described in further detail with reference to FIG. 8.

While FIG. 1 represents a variable resistance element 108 as a RRAM element 110 and a capacitor (Cₘᵣ 112) connected in parallel it will be understood that, in the present embodiment, the variable resistance element 108 corresponds to the RRAM element 110 which provides both a resistance and a capacitance. Therefore, the variable resistance element 108 may be referred to as the RRAM element 110, however, it will be understood that RRAM element 110 provides both a resistance and a capacitance.

The physical RRAM will include some parasitic capacitance and therefore the RRAM element 110 and Cₘᵣ element 112 together act as the real, physical RRAM device. In some embodiments, a larger Cₘᵣ may be engineered to maintain the parasitic capacitance artificially high. In some embodiments, there may be advantages in increasing the parasitic capacitance to ensure that other parasitics in the circuit do not substantially disrupt the divider

The variable resistance element 108 is a non-volatile element in which stored data remains when the power supply is turned off. In particular, the variable resistance element 108 is capable of retaining a resistance in the absence of power. In the present embodiment, the variable resistance element is controllable to be in one of two resistance states: a high resistance state (HRS) and a low resistance state (LRS) and to remain in that respective resistance state in the absence of power. By being switchable to and remaining in one of two resistance states, the resistance element 108 can store binary data. In the following embodiments, the high resistance state is representative of a 1 bit and the low resistance state is representative of a 0 bit. The memory cell thus may be referred to as a bit cell.

The variable resistance element 108 can be any type of resistive element capable of retaining resistance and thus storing data. For example, the variable resistance element may formed from a phase change material (PCM) device, a magnetic tunnel junction (MTJ), or a memristor element. As described in the following, the variable resistance element 108 could be a programmable resistor capable of being in one of two (in the present embodiments) distinct resistance states. The memory element may be a non-volatile switch of any kind (including floating gate MOSFET like in Flash memory). It will be understood that the variable resistance element is operable to be in one of a number of resistance states and to have such that the resistance of the element is set using electronic signals and the resistance is retained.

The memory cell 100 also has a capacitor, referred to as a bottom capacitor, or a ballast capacitor 114 (C_{b}) that is connected to the RRAM 110 in a capacitance divider arrangement. The electronic coupling between the RRAM 110 and the bottom capacitor 116 may be referred to in the following as the capacitor divider link connection or the link connection for brevity. The link connection between the RRAM 110 and the bottom capacitor has a node, also referred to the mid-point node 116 or a common node.

As described above, the dotted capacitance Cₘᵣ is the parasitic capacitance introduced by the RRAM MIM structure, whose size is determined by the area of the fabricated RRAM. The bottom capacitor Cb is chosen as a Metal-Oxide-Metal (MOM) capacitor which uses inter-digitated fingers, generates higher unit capacitance than MIM capacitors and can be built to a smaller minimum size (in different technologies different choices of capacitor). MOM caps may have advantages over MIM. For example, MIM caps may be denser than MOM caps and also may have a larger minimum size. Hence, MOM is selected in this embodiment.

In the present embodiment, the memory cell 100 is served by the following lines: cue 120, cue_bar 122, switch line (sw) 124, power switch line (psw) 126, matchline 128, and enable (en) line 130. The power switch line may also be referred to as a pulsed switch line.

As described in the following, for a content addressable read (CAR) operation, cue 120 and cue-bar 122 represent the data being search and may be referred to as first and second input data lines, respectively, or search lines. Cue and cue-bar are connected to either end of the capacitance divider arrangement. The values of cue and cue-bar are representative of the query data for a CAR operation. In the present embodiment, when searching for a ‘1’, cue is set to VSEC and cue-bar to GND and vice versa for a ‘0’. Additionally, if both cue and cue-bar are set to GND, the system performs a “don't care” search operation (also referred to as ‘X’ search operation).

In the present embodiment, the RRAM LRS is defined as 112 kΩ and HRS as 8.04 MΩ. The circuit is operated with a primary 1.8V supply voltage VDD and an adjustable secondary supply voltage VSEC, here designed to range within 1 to 1.4 V. VSEC is applied to cue/cue-bar and precharge signals only.

Switch line 124 and powered switch line 126 are connected to the write transistor 102 and control operation of the write transistor. In write operations, the switch line 124 and powered switch line 126 control the write transistor to switch the resistance state of the variable resistance element 108 thus allowing data to be written to the variable resistance element 108. It will be understood that the write transistor forms part of a write circuitry for writing data to the RRAM by applying a voltage to the RRAM. The switch line 124 and powered switch line 126, together or separately, may be referred to as write lines or RRAM programmable lines. In address addressable mode, the powered switch line may be referred to as an address addressable read line.

Matchline 128 is coupled to the output transistor 104. For a content addressable read operation, the value of the matchline is representative of the result of the content addressable read.

En line 130 is coupled to the further transistor 106. In the present embodiment, the EN line has a dual role: a) It ensures that the matchline is interfered with only when the mid node voltage is at a valid value and it ensures that the exact duration for which the matchline is interfered with is precisely controlled. That may provide fully controllable and consistent dynamics.

The circuit arrangement of the memory cell 100 is described in the following, for the present embodiment. The RRAM 108 is connected at a first end to the cue line 120 and at its second end to the link connection. The link connection connects the RRAM 108 to the bottom capacitor 114. As described above, the RRAM 108 is configured to be either a high resistance state (HRS) or a low resistance state (LRS). Together the RRAM 108, the link connector including mid-point node 116 and the bottom capacitor 114 can be considered to form a capacitance divider or a capacitive voltage divider. The capacitance divider is connected at a first end to the cue line 120 and at the second end to the cue bar line 122. The divider mid-point node 116 directly drives the output transistor. As described in further detail with reference to FIG. 2(a) and FIG. 2(b), the capacitance divider is operable in dependence on the resistance state of the RRAM.

The write transistor 102 is connected at its gate electrode to the switch line 124. The write transistor 102 is connected at its drain to the node between the RRAM 110 and the bottom capacitor 114. The write transistor 102 is connected at its source electrode to the psw line 126. As described with reference to FIG. 7, the write transistor 102 is operable to set the resistance state of the RRAM and thus write data to the memory cell. In read operations, the write transistor 1022 acts as a deadweight capacitor. The write transistor 102 may be alternatively referred to as a programming transistor.

The output transistor 104 is connected at its gate electrode to the mid-node 116 of the capacitance divider. The output transistor is connected at its drain to the matchline 128. The output transistor 104 is connected at its source electrode to the drain electrode of the further transistor 106. The output transistor 104 has a threshold voltage corresponding to the minimum gate to source voltage required to create a conduction path between source and drain. As described above the further transistor 106 is operable to enable reading of data and to form part of a read out transistor arrangement with output transistor Q2, 104. For a content addressable read, the further transistor 106 is used to enable a content addressable read that includes a discharge path of the matchline.

There may be a relationship between the threshold voltage and the values of the other components in the circuit. Selection of the threshold voltage may involve a complex process where the available transistors are checked (for example, there may a number of different types of low voltage nMOS transistors available) and systems are designed to minimise energy in all of them. The general logic states that the lower a threshold voltage, the lower the VSEC supply can become and thus save power. If the threshold is too low, then even in the OFF state, Q2 may leak too much and discharge the matchline when undesired. In general, a lower threshold may be preferred for that reason.

The further transistor 106 is connected at its gate electrode to the en line 130. The further transistor 106 is connected at its drain electrode to the source electrode of output transistor. The further transistor 106 is connected to ground at its source electrode. The further transistor 106 is coupled to the en line, as described above.

In the present embodiment, the memory cell 100 is connected to a pre-charging transistor 136. The pre-charging transistor 136 is connected at its gate electrode to a pre-charging input (pre_1 line 132) and at its drain to a high supply voltage 134 (Vdd) and at its source to the matchline. The pre-charging transistor 136 operates to increase the voltage of the matchline 128 of the memory cell to a high voltage supply level 134, in response to receiving the pre-charging input signal 132 at its gate.

As outlined with reference to FIG. 1, the capacitance divider is operable in dependence on the resistance state of the resistance element 108. For illustrative purposes, FIG. 2(a) and 2(b) depict equivalent circuits for the capacitance divider arrangement of FIG. 1 when the variable resistance element is in the high resistance state and in the low resistance state, respectively. The RRAM element may be considered to operate as a switch in these two states. In particular, the resistance value of the high resistance state is sufficiently high that the RRAM operates as an open switch while providing a capacitance value. Likewise, the resistance value of the low resistance state is sufficiently low that the RRAM operates as a closed switch, effectively by-passing the capacitance. Therefore, when the variable resistance element 108 is in the HRS, the capacitance divider circuit operates in a capacitance divider mode. In the capacitance divider mode, the voltage provided to the capacitance divider is shared between the RRAM and the bottom capacitor. In such a mode, the current through the RRAM is permitted to flow. When the variable resistance element is in the LRS, the capacitance divider operates in a by-pass mode, in which the capacitance of the RRAM (Cₘᵣ) is bypassed. In LRS, the cue line floods the mid node and charges the ballast capacitor Cb. In LRS therefore, there are substantially no DC paths, however, all of the current that passes into the mid node passes there through the RRAM. In such embodiments, in the LRS, the voltage shared with the RRAM across the voltage divider arrangement is reduced compared to when in the HRS. In the HRS the current flow is blocked, thereby allowing the capacitors to act as a voltage divider.

Therefore, as depicted in FIG. 2(a), when the RRAM is in the HRS (in this embodiment, in MΩ) the variable resistance element 108a may be represented as an open switch 109 and capacitor Cₘᵣ 112 in parallel. The RRAM thus provides a parasitic capacitance Cₘᵣ and, together with the capacitance of the bottom capacitor C_{b}, functions as a capacitor or capacitance divider. As depicted in FIG. 2(b), when the RRAM is in the LRS, the capacitance divider operates in a by-pass mode and thus the variable resistance element 108b may be represented as a closed switch 109b.

In operation, when the RRAM is in the LRS the voltage reading at the mid-point node (Vmid) is dependent on the value of cue, in particular, the voltage reading at Vmid follows cue. In practice, because the LRS used is relatively high (in this embodiment, 112 kOhms), effective capacitive divider modulation is obtained by shifting the RRAM-Cₘᵣ RC constant. This is especially important at high frequencies (100s of MHz). At the same time, the behaviour of Vmid also depends on the cue/cue-bar values, resulting in the Table 1 of FIG. 3. In particular, when the cue input does not match the stored data (corresponding to a ‘miss’), Vmid goes high, Q2 activates and match-line ML discharges. Thus, the matchline can be considered as an ‘OR match-line’. In addition, a cue line value equal to cue-bar line value equal to GND yields ‘don't care’. In embodiments where a group of more than one cell is coupled to a common match-line, the match-line remains at an elevated level when every cell of a group of cells (for example, a column or row of an array) registers no ‘miss’.

FIG. 3 is a table of results depicting values of the resistance state of RRAM, the corresponding voltage at the mid-node (Vmid) and the resulting voltage level at the matchline.

In the first two rows, the cue line has a value corresponding to a search for a 1. In the third and fourth rows, the cue line has a value corresponding to a search for a 0. In the fourth and fifth rows, the cue line has a value corresponding to “don't care” search (search for X). For each search, the table represents results for when the stored data corresponds to a 0 data bit (the RRAM is in the LRS) or a 1 data bit (the RRAM is in the HRS).

When the RRAM is in the HRS, the circuit operates in the capacitance divider mode. Therefore, for a search for a 1, the value of Vmid is low. In particular, the value of Vmid is lower than the threshold of the output transistor 104 and therefore the match line remains high. For a search for a 0, the value of Vmid is high, in particular, higher than the threshold voltage of the output transistor 104. Therefore, the matchline provides a low output. When the RRAM is in the LRS, the circuit operates in the by-pass mode. Therefore, for a search for a 1, the value of Vmid is high, in particular, the value of Vmid is higher than the threshold of the output transistor 104 thus causing the match line to be low. For a search for a 0, the value of Vmid is low, the value of Vmid lower than the threshold of the output transistor 104 and therefore the match line remains high. For a “don't care” search, in both high and low resistance states, a search for a 0 and a search for a 1 leads to a low Vmid and thus a high match-line. The threshold voltage of the output transistor 104 is such that the matchline is switched and takes a high or low value, in dependence on whether the data represented by the first data line and the second data line matches the data stored in the memory element. In the present embodiment, for a match, the match line remains high and for a non-match the match line takes a low value.

It will be understood that, the values of the LRS and HRS are such that, in the LRS, the voltage divider circuitry operates in the by-pass mode and bypasses Cₘᵣ and in the HRS the capacitor divider operates as a capacitor divider, also referred to as in the capacitor divider mode. It will be understood that the capacitor divider is an example of a voltage divider and may be referred to, in some embodiments, as a capacitive voltage divider.

FIG. 4 is a timing diagram for performing a content addressable read (CAR). It will be understood that the write transistor (Q1) is switched off for the content addressable read operation. FIG. 4 depicts the CAR sequence in detail for a preliminary portion 202 and three successive search operations: a search for a 1 data bit (search 1 operation 204), a search for a 0 data bit (search 0 operation 206) and a “don't care” search (search X operation 208). The elapsed time for each of the search 1, search 0 and search X operations can be further split into an earlier and later portion, also referred to as a query stage and a result stage. The values of voltages depicted in FIG. 5 are: sw line 210, cue line 212, cue-bar line 214, psw line 216, pre-charge line 218, en line 220, mid-point node voltage (Vmid) 222 and matchline 224 (also referred to as ML). FIG. 4 depicts the waveforms for each of these lines.

During the initial stage 202, a precharge voltage is provided to the precharge transistor to increases the match line ML 224 to a voltage level VDD, and then the precharge transistor is turned-off. Before each search operation, the sw line 210 is opened to clear any residual charges at the mid-point node (shown as Vmid 222). The matchline ML is then pre-charged to the supply voltage level VSEC for 1× clock cycle. At the same time, cue and cue-bar start to rise for 2 ns in accordance with the cue date. For the search 1 operation, cue is set to a higher voltage (VSEC) and cue-bar is at a lower voltage (GND) during the search 1 query stage 204a. For the search 0 operation 206 cue is at a lower voltage (GND) and cue-bar is at the higher voltage (VSEC) during the search 0 query stage 206a. For the search X operation 206 both cue and cue-bar are at the lower voltage (GND).

In response to setting the query data (the cue and cue-bar lines), during the search 1 query stage 204a the voltage at the mid-node (Vmid) starts to accumulate charge and beings to increase. In contrast, during the search 0 query stage 206a, the voltage at the mid-node starts to dissipate and begins to decrease. The voltage at the mid-node exceeds the threshold voltage of the output transistor when a mismatch between the input data and the stored data is detected. Thus, for the search 1 operation, when in the low resistance state, the voltage at the mid-node rises at a higher rate and to a higher value than when in the low-resistance state. Likewise, for the search 0 operation, when in the low resistance state, the voltage at the mid-node decreases at a higher rate and to a lower value than when in the high-resistance state. This is because at the high resistance state, the capacitance divider part acts as a capacitance divider, while in the low resistance state, the capacitance divider part by-passes the capacitance Cₘᵣ.

During the query stages, the matchline voltage is initially substantially equal for both resistance states. The en line is then strobed when the value of Vmid has stabilised sufficiently. Following the strobing the voltage at the mid-point node is returned to zero for both search operations. For the search 1 operation, following the strobing, the matchline voltage increases to its upper limit, when in the high resistance state and decreases to zero when in the low resistance state. Likewise, for the search 0 operation, following the strobing, the matchline voltage decreases to 0 when in the high resistance state and increases to its upper limit when in the low resistance state.

Following the query stages 204a, 206a of each type of search operation there are result stages 204b, 206b. During the result stages, the voltages at cue and cue bar are both returned to zero and the results can be read from the matchline voltage. For a “hit” (search operation for a 1 in the HRS and a search operation for a 0 in the LRS) the matchline remains at an elevated level. For a “miss” (search operation for a 1 in the HRS and a search operation for a 0 in the LRS) the matchline is at a lower level.

It will be understood that the memory cell described above may store one bit of data. Multi-bit data can be checked by chaining multiple cells with the same matchline. Every bit miss degrades the ML voltage level so that a percentage of hit/miss can also be observed given sufficiently sensitive sensing circuitry.

### Address Addressable Read

As described above, the memory cell of FIG. 1 may also be used for address addressable read (AAR) operations. FIG. 5 is an equivalent circuit diagram of a memory cell 300, also referred to as a memory pixel, for performing the AAR operation.

It will be understood that the circuit of FIG. 5 corresponds to the memory cell depicted in FIG. 1, with a 1T1R structure (Q1 and RRAM) activated and the other part of the circuit remaining off for the duration of the AAR operation.

The circuit has a memory cell 300 coupled to a peripheral circuit 303 for an address addressable read operation, in accordance with an embodiment. The cell components: RRAM 310, mid-point node 316, bottom capacitor 314, switch line 324, powered switch line 326 and write transistor 302 are substantially as described with reference to FIG. 1. In particular, RRAM 310 and bottom capacitor 314 are arranged in a capacitance divider arrangement. For the purpose of performing AAR operations, both cue and cue-bar lines are set to ground.

The peripheral circuit 303 has a first transistor 340, also referred to as Q4, a second transistor 342 also referred to as Q5 and a tank capacitor 352. The first transistor 340 is connected at its source electrode to the drain electrode of the second transistor 348. In the connection between the first transistor 340 and the second transistor 342 is a further mid-point node 344. The first transistor 340 is connected at its drain electrode to a supply voltage (Vsec) 346. The gate electrode of the first transistor 346 is connected to a sec line 348. The gate electrode of the second transistor 342 is connected at its source electrode to ground. The gate electrode of the second transistor 342 is connected to a clr line 350. The further mid-point node 344 is connected to the write transistor 302 of the cell 300, in particular, to the source electrode of the write transistor 302 via the psw line 326. A tank capacitor 352 is connected between the further mid-point of the peripheral circuit and the source electrode of the programming transistor 302.

Operation of the circuit of FIG. 5 is described with reference to the timing diagram of FIG. 6. The timing diagram depicts timings of the clr 350, sec 348, sw 324 and psw 326 lines. The waveforms for each of these lines are depicted by: clr waveform 362, sec waveform 364, switch waveform 368 and psw waveform 370, respectively. For the purpose of performing AAR, both cue and cue-bar are set to ground. In some embodiments, the PSW line 326 is connected a group of a plurality of memory cells, for example, a row or column of an array arrangement. In this embodiment, the parasitic capacitance of the line on psw creates a charge tank representing the equivalent charge level when RRAM is at different states. Capacitor 352 can be represented by the line capacitance that services the entire row (or column) of pixels that share PSW. Thus, in some embodiments, the capacitor 352 is not physically implemented. The more pixels hanging from the same PSW line, the higher the line capacitance. Depending on the value of the RRAM that capacitance will need to be of a certain level. For example, if the RRAM is in HRS it must not discharge in a single AAR cycle (e.g. the strobing of SW between 4-5 ns) but if it is in LRS, it must discharge in the same interval. For any RRAM, the resistance or resistive state, R, and speed of strobing there is an optimum capacitance. In some embodiments, the memory size is selected such that the line capacitance is that optimum. Ideally we do not want an explicitly implemented capacitor 352. In addition, the lower the capacitance, the lower the power consumption.

At a first step, psw line 326 is initially cleared by signal clr 350 to open the transistor Q5 342. At the next step, a 1 ns strobing at the sec line 348 sets psw 326 to the supply voltage VSEC 346. Finally, the sw 324 line is strobed and allows the psw line capacitance to discharge. The discharging of the capacitance and thus the operation of the capacitance divider is dependent on the resistive state of the RRAM being read. In particular, if the RRAM is in the HRS, the line discharges at a slower rate that when in the LRS. Further sensing circuitry, for example, circuitry associated with the tank capacitor allows the result to be read. In further detail, as soon as SW line is activated, capacitor 352 shares charge with all the other capacitances (314) hanging on the same PSW line thus providing the initial drop in FIG. 6. At that point, the differences in discharge rates, described above, occur.

In the present embodiment, the sensing circuit sensed the voltage and determines if the voltage represents a 1 or a 0. As a non-limiting example, the sensing circuity is a strong-armed latched comparator. In some embodiments, only the plurality of cells connected to the common psw line (for example, a column or row of an array of cells) are activated.

### Write Operation

As described above, the memory cell of FIG. 1 is further configured to perform one or more write operations. FIG. 7(a) and 7(b) depict equivalent circuits 400a and 400b, respectively, to illustrate the write operation using the memory cell. The performed write operation may be a write forward or write reverse operation. The performed write operation may be an assisted write forward or an assisted write reversed operation.

The RRAM element 410, the bottom capacitor 414, the write transistor 402 and the mid-point node 416 of the equivalent circuits 400a, 400b are as described with reference to the memory cell of FIG. 1. The cue line 414, the sw line 424 and the psw line 426 are also as described with reference to FIG. 1. As described with reference to FIG. 1, the write transistor 402 is connected to the mid-point note 416 at its drain electrode. The write transistor 402 is connected to switch line 424 at its gate electrode and the psw line 426 at its source electrode. It will be understood that, in some embodiments, the write transistor 402 forms part of a write circuitry for writing data to the RRAM element 410.

In FIG. 7(a), the cue-bar line is set to ground. The cue-bar is set such that the bottom capacitor 414 is connected at one end to the RRAM element 410 (via the mid-point node 416) and at its second end to cue-bar set to ground. In contrast, in FIG. 7(b) the bottom capacitor 414 connected at one end to the RRAM element 410 (via the mid-point node 416) and at its second end to the cue-bar line. It will be understood that, in both circuits, Cb is connected at its second end to cue_bar, however, cue_bar may be set to different voltage levels. In FIG. 7(a) cue_bar is left unmoving at GND. In FIG. 7(b), cue_bar may be modified in order to perform the “write boost” operation. It may be be left at GND for an unboosted operation.

In the embodiments of FIG. 7(a) and 7(b), the writing or programming of data to the RRAM element is performed using pulses. To write the RRAM element to its desired state, a bias voltage can be applied at the cue and psw terminals. Forward direct writing is defined when a bias voltage is applied at cue and psw is connected to GND. A reverse direction write is achieved by setting psw to Vdd and keeping cue grounded. After biasing, sw is pulsed resulting in a voltage applied across the RRAM. For a standard write operation, cue is either GND or bias voltage, depending on direction of writing.

The placement of Cb 414, as shown in FIG. 7(b), may allow an assisted write operation to boost the voltage delivered across the RRAM, as shown in FIG. 7(b). The assisted write operation may guard against ‘stuck-at’ faults. This assistance is achieved by sending pulses at cue-bar simultaneously to sensing pulses at sw. The simultaneous delivery of pulses at sw and psw may temporarily boost the voltage delivered across the device via charge-pump action.

FIG. 7(c) depicts a signal timing diagram to illustrate a write operation for the memory device, in accordance with an embodiment. It will be understood that the write operation may be performed by the memory device represented by the equivalent circuit of FIG. 7(a).

FIG. 7(c) shows a switch line waveform 702 for switch line 424 and the resultant resistance state of the RRAM 410. For the purposes of the following description, FIG. 7(c) has three phases. FIG. 7(c) shows a first phase 702, in which a 1 data bit is written to the RRAM 410. Writing of 1 data bit corresponds to changing the resistance state of the RRAM 410 from a LRS to a HRS. This is achieved by providing a pulsed voltage waveform at the switch line 424 while setting the cue line 414 to GND and the PSW line 426 to Vdd. It will be understood that, while FIG. 7(c) depicts three pulses, this is for illustrative purposes only. The number of pulses over a time period will be dependent on the RRAM properties.

Following the first phase is a second phase 708, during which the RRAM 410 remains in a high resistance state. During this phase 708, the RRAM 410 continues to store the written data. No signals are applied during the second phase.

Following the second phase, FIG. 7(c) illustrates a third phase, in which a 0 data bit is written to the RRAM 410. Writing of 0 data bit corresponds to changing the resistance of the RRAM 410 from a HRS to a LRS. This is achieved by providing a pulsed voltage waveform at the switch line 424 while setting the cue line 414 to Vdd and setting PSW line 426 to GND.

FIG. 8(a) depicts a first view of a RRAM device in accordance with embodiment and FIG. 8(b) depicts a cross-sectional view of the RRAM device. FIG. 8(a) and (b) depict a substrate 902 on which a CMOS metal layer 904 is provided. A RRAM top electrode layer 906, a RRAM dielectric layer 908, and a RRAM bottom electrode layer 910 are provided. The RRAM dielectric layer is provided between the top and bottom electrode layers. A via 912 is provided for connecting the bottom electrode to the CMOS metal. Line 922 outlines the active device.

FIG. 8(a) and 8(b) illustrate the physical, in-pixel RRAM position. The active device is placed above the CMOS metal layer 904. FIG. 8 depicts only the uppermost topmost CMOS metallisation layer of Cb for clarity. The pixel transistors and other layers are hidden below this metal layer and therefore not shown. The cross-section view is obtained from the cut-line 920 dissecting the top view. FIG. 8(b) depicts a top view of the device. Via layer 912 is not exposed in the top view and hidden under the top, dielectric and bottom electrode layers. Likewise, bottom electrode layer is partially exposed and partially hidden by the upper layer. In accordance with an embodiment, the RRAM device has an area of 0.35 μm×0.35 μm and its capacitance is approximated to 2.2 fF based on measurements of physical RRAM devices.

While FIG. 8 depicts a construction in accordance with an embodiment, it will be understood that the circuit may be implemented using different material stacks and constructions. As non-limiting examples, the circuit may include Metal-Oxide based RRAM with Pt/AlOx/TiOx/Pt and Ag/SnOx/Pt and Ag/ZnOx/Pt material stacks.

FIG. 9 depicts a memory system 500 including a 64×64 array 502 of CAM pixels, in accordance with an embodiment. Each pixel substantially corresponds to the memory cell 100 of FIG. 1. It will be understood that groups of pixels will have one or more common or shared readout and/or write lines. In further detail, in the embodiment of FIG. 9, each column of pixels of the array has a shared match line allowing data, for example in the form of binary bit strings, to be stored in columns. Each column of pixels have a shared PRE, EN and SW line so that the connected matchline can provide an equivalent voltage level indicated comparison similarity. In the present embodiment, CUE and CUE_BAR are connected horizontally. PSW is also connected to horizontally to allow AAR operations for each row.

To analyse the outcome of CAR and AAR operations, a first latch comparator 504 and a second latch comparator 506 are coupled to the output of the 64×64 array. The latch comparators are MOS type latch comparators. The comparators may be, for example, either pMOS or nMOS differential pair types. The latch comparators are designed to resolve the potentially very small gap between an ‘all-hit’ and a ‘1-bit miss’ scenarios for CAR and the result differences between HRS and LRS-induced outcomes at PSW for AAR.

CUE is operated at the secondary adjustable power supply VSEC for CAR operation but requires reaching the primary power supply VDD for write operations. Additionally, the circuit is configured to switch the signal at PSW between the multiple supply voltages and GND under different operation conditions. This is achieved via 3× transistors, with PRI connecting to the primary 1.8V supply and SEC to VSEC. As for cue-bar, it operates at VSEC for CAR but stays at the VDD or GND for the other operations. An additional signal SUPSW is introduced to swap between the supply voltages.

To enable parallel CAR searching, each row is provided with a corresponding peripheral circuit 510 and signal driving circuitry 512 so that the entire array may be activated at the same time.

At a higher level, the chip has input circuitry including de-serialiser 513, a finite state machine circuitry 514 and flip flop circuitry 516. The de-serialiser 513 receives inputs and processing the incoming information. The de-serialiser 513 splits the information splits into address information, data information and instruction information. The finite state machine 514 is configured to receive the address, data and instruction information and generates all control signals for the array 502. The signals are gated by a group of flip-flop components of the flip flop circuitry 516 for synchronisation. The output of the flip flop circuitry 516 is then delivered to the driving circuitry 512 and the peripheral circuitry 514.

The chip also has output circuitry. The output circuitry includes a CAR serialiser 518 and an AAR serialiser 520. The outputs from CAR and AAR operations are sent to their corresponding serialisers and then output to further components not shown in FIG. 9. The further components may be provided on the same chip. In the present embodiment, an internal clock running at 800 MHz to synchronise the control signals is used. FIG. 9 also depicts ring oscillator 522, multiplexer 524 and frequency divider 526. The ring oscillator 522 is configured to generate the clock signal. In the present embodiment, the ring oscillator is an adjustable, current-starved oscillator. The multiplexer 524 provides a failsafe such that if the ring oscillator fails during operation, a clock signal can be passed into the system. The frequency divider 526 is a standard module configured to produce a reduced frequency version of the clock signal in powers of 2. In the present embodiment, the clock signal is divided by eight. This may provide a readable back-up/diagnostic signal off chip and ensure that the ring is operating.

In the above described embodiments, the resistance states LRS and HRS are described as having values of 112 kΩ and 8.04 MΩ respectively.

It will be understood that different values of the LRS and HRS may be used to obtain the same functionality as described above. In addition the actual values may depend on the technology and manufacturing processes used. The values of the HRS and LRS are such that in the LRS the voltage divider circuitry operates in a by-pass mode is provided and in the HRS the voltage divider circuitry operates in a voltage divider mode.

In principle, a LRS tending to 0 may provide a clean by-pass of Cₘᵣ when in the LRS. If LRS tends to 0 there is no issue with functionality. As a non-limiting example, the LRS may be in a range of 100 to 1000 Ohms.

Regarding the HRS, in principle, a HRS tending to infinity will provide a clean cut of the bypass path. If HRS goes to infinity, there is no issue with functionality. As a non-limiting example, the HRS may be in a value above 10 MOhms.

With regard to values for the capacitance, Cₘᵣ may be substantially as large as the parasitic capacitances on the mid node, for example, element 116 in FIG. 1. As a non-limiting example, using CMOS 180 nm processes, Cₘᵣ may be in a range between 500-700 aF (atto-Farad), however, this may be 400 aF or less.

With regard to Cb, this will be a multiple of the Cₘᵣ, for example, 5 to 10 multiples of Cₘᵣ, preferably 5 to 6 multiples of Cₘᵣ. However, the actual values will depend on other factors, such as parasitics in the circuit. As a non-limiting example, using CMOS 180 nm processes, for example, Cₘᵣ may be substantially around 6 fF (femtoFarad). As a further non-limiting example, using CMOS 90 nm processes, that may be reduced further to about 5 fF or lower, depending on configuration. Cb is limited by Cₘᵣ but may be as small as we like.

A skilled person will appreciate that variations of the disclosed arrangements are possible without departing from the scope of the invention.

As a first example, in the above-described embodiments, the mid-point node is exposed primarily to four capacitances: a) the capacitance of the RRAM element Cₘᵣ, b) the bottom or ballast capacitance C_{b}, c) the parasitic capacitance of the write transistor Q1 (C_{q1}) and d) the parasitic capacitance of the output transistor Q2 (C_{q2}). FIG. 10 depicts an alternative embodiment in which the bottom capacitor is removed in which the bottom (or ballast) capacitor is removed from the memory cell and instead part of the capacitance divider is provided by a parasitic capacitance of the write transistor Q1. The parasitic capacitance of Q1 is paired with the parasitic capacitance of the RRAM to form the capacitance divider. In such an embodiment, the capacitance of Q1 provides all of the necessary capacitance for operation and therefore takes the role of Cb, without an additional C_{b} component.

As described with reference to FIG. 1, the memory cell 600 has the same components: variable resistance element 608, RRAM 610 with parasitic capacitance represented by Cₘᵣ 612, write transistor 602, output transistor 604 and further transistor 606. The memory cell is served by cue 620, cue-bar 622, switch line 624, and matchline 628. In such an embodiment, the capacitance value of Cₘᵣ may be reduced to a lower value than that used in FIG. 1. It will be understood that the value will be determined based on parasitics in the system. This will be determined by the parasitics around the system. As a non-limiting example, the capacitance value may be as low as 0.44 fF (compared to 2.2 fF). In FIG. 10, the parasitic capacitance of the write transistor Q1 takes the place of the bottom capacitance and plays the same role of equalising the capacitance divider.

In the above described embodiments, the bottom capacitor provides the main contribution to capacitance in the system. The bottom capacitor can be understood as the main energy storage device where the charge sits when the memory contents are assessed in CAR. Cₘᵣ then acts as a counterweight to it, which is either present or absent depending on the RRAM (as described above, this may be present or absent in dependence on the resistance state of the RRAM).

In this embodiment, the PSW and CUE_BAR lines are combined. In the CAR operation, it was observed at FIG. 4 that PSW and CUE_BAR were synchronised therefore PSW and CUE_BAR may be combined. In the AAR operation, modification of the peripheral circuits can be made to allow the cue-bar peripheral to remain tri-stated (so in a high impedance state, Z, there is no active driving allowed on them) while the PSW peripheral circuit controls and operates the combined PSW and CUE_BAR line. Likewise, for the write operation, the peripheral cue-bar circuit is tri-stated and the PSW peripheral circuit controls and operates the combined PSW-cue-bar line. The PSW and CUE_BAR drivers may be merged together in embodiments. In such embodiments, the three transistors previously coupled to CUE_BAR are now controlling the operation of the device. The only further modification is the logic that determines which one of the transistors is in control of the line at any given point in time.

As a further example, in the above-described embodiments, a capacitance divider arrangement is described. It will be understood that alternative voltage divider arrangements may be used in accordance with further embodiments. In general, a voltage divider arrangement that can divide voltage based on the impedance or resistance state of a memory element may be implemented. For example, an impedance divider arrangement in which the memory element has a high or low impedance state may be suitable.

As a further example, in accordance with embodiments, the voltage divider may be any impedance divider with one or more impedances of the divider, or the components providing the impedance of the divider, having a reactance component. It will be understood that such an impedance divider may be implemented using different combinations of components. Both impedances may be described by Z=R+Xi where: Z is impedance, R is resistance, X is reactance (either capacitor-reactance or inductor-reactance) and i is the complex unit (square root of −1) and ii) X is non-zero. In a first non-limiting class of examples, R may be non-zero and variables/changeable. In a second non-limiting class of examples, the pure capacitive divider case, R may be zero but the capacitance is variable/changeable. A further set of examples includes the case where R is non-zero and both R and C are variable/changeable. A further class of examples, includes the case where R is non-zero and X is either of C-form (capacitance) or L-form (inductance) or a mixture of those and X is variable/changeable either via capacitance or inductance or both.

It will be understood that the one or more impedance states may be either solely reactance or resistance states or a combination of reactance and resistance. It will be understood that in embodiments, in which a high and low impedance state is discussed, the resistance and reactance contributions are combined in a vector format to create a single, overall impedance vector and the high and low impedance states refer to the magnitude of the impedance vector. Furthermore, it will be understood that the values of the high and low impedance states will be such that, in the low impedance state the voltage divider circuitry operates in a bypass mode and bypasses Cₘᵣ and in the high impedance state the voltage divider circuitry operates as a voltage divider.

As a further example, the above-described embodiments relate to memory elements that are writeable, in that the resistance state can be set by write circuitry. Alternative voltage divider embodiments using fixed value components may also be implemented in accordance with embodiments. As a first non-limiting example, a voltage divider arrangement based on a resistor divider may be used. In such an example, the resistors are not variable/programmable but rather have fixed resistance values. The resistors are selected such that the arrangement of different resistors can represent data. While such a device may only offer read only capabilities, such a device may provide security advantages as the resistors can be visually inspected to identify tampering. In such an example, the resistors could be selected such that the high and low resistance states approximate an infinite and zero resistance system. A capacitance divider based arrangement using fixed-value capacitors may also be implemented. In a related, alternative embodiment, a voltage divider arrangement having fixed impedance values is provided.

As a further non-limiting example, the RRAM element may be replaced by a memcapacitor element. The memcapacitor may allow for a clean one or zero (in which there are no DC paths and therefore there is no charge shuttling in and out of the mid-node except when resetting) to be applied and may allow for operation at any frequency as far as any leakage currents may allow. In principle memcapacitors may allow for every possible frequency. Logically speaking the 1 and 0 may be as clean as the ratio of component impedances allows. In the limit case of having memcapacitors, there is never any exchange of charge between the mid node or CUE and CUE_bar except when resetting. In such an embodiment, the memcapacitor may be paired with a further element such as a resistor or a capacitor in a voltage divider arrangement.

As a further example, in the above-described embodiments, a non-volatile RRAM element is described. In an alternative embodiment, a volatile memory element may be used that only holds data temporarily. Such a device may be used for a so-called scratchpad memory or other temporary memory that is configured to store temporary data. Such temporary data may relate to, for example, objects that the system is currently attending to. Such an embodiment may be implemented, for example, by modifying the relative frequency of the read and write operations.

In the above described embodiments, the memory circuit is described as operating in a content addressable memory. In some embodiments, the same circuit may act as one or all of a CAM, a non-volatile RAM and a volatile RAM. As a further example embodiment, the memory device is operable as a volatile DRAM for temporary storage of data. The DRAM embodiment may be considered as a polymorphism to the associative memory. If a search is not required, the circuit may be operated in a dynamic random access memory (DRAM) mode as follows. In such a mode the capacitor is used to store data as a charge.

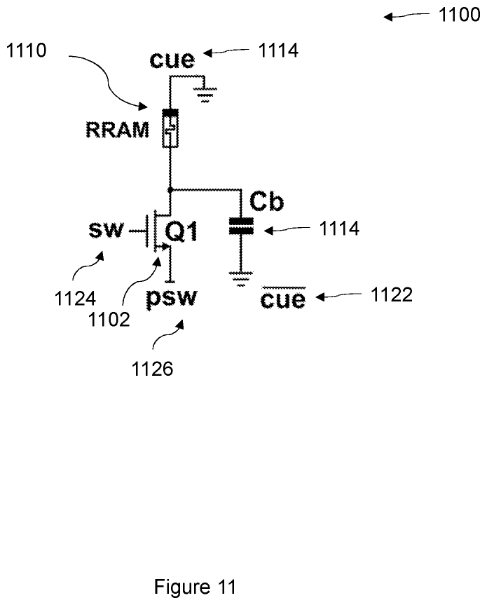

Firstly, the cue lines (cue and cue-bar) are set to ground. The write transistor can then act as a transistor in DRAM mode. The EN on match-line (not shown) is kept OFF, thus obtaining an equivalent circuit as depicted in FIG. 12.

The equivalent circuit of FIG. 12 shows write transistor 1202, RRAM element 1210, capacitor 1214, cue line 1214, cue-bar line 1222, sw line 1224 and psw line 1226.

To operate as a DRAM, the RRAM element 1210 is controlled to be set a high resistance state, preferably a very high resistance state. During operation as a DRAM device, the RRAM element remains at the high resistance state. Both cues lines are connected to the ground. The data is then stored as a trapped charge on the capacitor 1214. The PSW line 1226 can then be operated as a bit-line and the sw line 1222 can be operated as a word-line to let the write transistor 1202 act as a transistor in a DRAM mode (i.e. to perform read and write operations).

It will be understood that the memory circuit is therefore operable to store all of the below: volatile and non-volatile content-addressable memories stored as component values, volatile and non-volatile address-addressable memories stored as component values and volatile address-addressable memories stored as electrical signals (independent of component values).

Further it will be understood that the variable resistance element may, in some embodiments, be a variable resistance device and formed of more than one component that operate together to be in a resistance and/or impedance state representative of at least part of the data,

Accordingly, the above description of the specific embodiment is made by way of example only and not for the purposes of limitation. It will be clear to the skilled person that minor modifications may be made without significant changes to the operation described.

What is claimed is:

1.-25. (canceled)

26. A memory device for storing data comprising:
voltage divider circuitry comprising at least one memory element, wherein the at least one memory element is operable or selected to be in a resistance and/or impedance state representative of at least part of the data,
wherein the voltage divider circuitry is configured to divide a voltage in dependence on the resistance and/or impedance state of the at least one memory element as part of a data read and/or a data write operation, wherein the at least one memory element is capacitive and is connected to one or more further capacitive elements such that the voltage divider circuitry comprises a capacitor divider arrangement.

27. The memory device according to claim 26, wherein the voltage divider circuitry is configured to avoid and/or at least reduce resistive paths during the data read and/or data write operation of the at least one variable resistance memory element.

28. The memory device according to claim 26, wherein the at least one memory element is operable to be in a high or a low resistance and/or impedance state and wherein the voltage divider circuitry is configured to at least reduce the voltage shared with the least one memory element of the voltage divider circuitry when the at least one memory element is in a low resistance and/or impedance state.

29. The memory device according to claim 26, wherein the voltage divider circuitry is configured to share the voltage between the at least one memory element and the one or more further elements when the at least one memory element is in a high impedance state.

30. The memory device according to claim 26, wherein the voltage divider circuitry is configured to operate as a capacitance divider when the at least one memory element is in a high resistance and/or high impedance state.

31. The memory device according to claim 30, wherein the parasitic capacitance of the memory element, optionally of one further element, provides part of the capacitance of the capacitance divider.

32. The memory device according to claim 26, wherein the at least one memory element is configured to substantially block and/or permit a current flow through the at least one memory element in dependence on the resistance and/or impedance state of the memory element.

33. The memory device according to claim 26, wherein the voltage divider circuitry comprises the at least one memory element connected to one or more further elements wherein the voltage divider is connected between a first data line and a second data line; and the device further comprises:
at least one output transistor connected between the at least one memory element and the one or more further elements such that a divided voltage is provided to the gate electrode of the at least one output transistor;
wherein the at least one output transistor is coupled to a matchline thereby to control the matchline in dependence on the divided voltage.

34. The memory device according to claim 33, wherein the at least one output transistor has a threshold voltage such that the matchline is switched in dependence on whether the data represented by the first data line and the second data line matches the data stored in the at least one memory element.

35. The memory device according to claim 33 further comprising at least one write transistor connected between the at least one memory element and the one or more further elements, wherein the at least one write transistor is operable to apply a voltage to the memory element thereby to write data to the memory element.

36. The memory device according to claim 33, further comprising at least one further transistor operable to enable reading of data from the at least one memory element, for example, as part of a content addressable read operation.

37. The memory device according to claim 26, wherein the voltage divider circuitry is coupled to one or more, optionally two, search lines for providing an input voltage representative of query data and the voltage divider circuitry is configured to output a voltage representing a match and/or a mismatch between the stored data and the query data.

38. The memory device according to claim 26, wherein the memory device is configured to perform a content addressable read operation.

39. The memory device according to claim 26, wherein the device further comprises read circuitry for performing the data read operation, wherein the data read operation comprises receiving an output voltage from the voltage divider circuitry, wherein the output voltage is dependent on at least the resistance state and/or the impedance state of the memory element, optionally wherein the read circuitry comprises at least one output transistor driven by the output voltage of the voltage divider circuitry.

40. The memory device according to claim 26, further comprising write circuitry for applying a voltage to the at least one memory state thereby to set the resistance state and/or impedance state of the at least one memory element, optionally wherein the write circuitry comprises at least one write transistor coupled to the voltage divider circuitry.

41. The memory device according to claim 26, wherein at least one of a), b), c), d):
a) the at least one memory element is selected to be in or is operable to be in one of a plurality of resistance and/or impedance states and/or wherein the at least one memory element comprises a variable resistance and/or variable impedance memory element operable to be in one of two or more resistance and/or impedance states;
b) the at least one memory element and, optionally, the one or more further elements comprises a non-zero reactance;
c) the at least one memory element is configured to retain the resistance and/or impedance state in the absence of power;
d) the at least one memory element is operable to be in at least a first resistance and/or impedance state or a second resistance and/or impedance state thereby to represent a binary data bit

42. The memory device according to claim 26, wherein the voltage divider circuitry is operable in one or more modes comprising at least: a content addressable read mode, an address addressable read mode and a write operation mode, optionally wherein the memory device comprises controlling circuitry configured to select the operational mode of the memory device.

43. The memory device according to claim 26, wherein at least one of a), b), c):
a) the memory device comprises a non-volatile memory device and/or wherein the memory device forms part of a bit cell or a memory cell;
b) the memory device is further operable as volatile memory and/or a dynamic RAM memory and/or operable to store data in a capacitor;
c) the memory element comprises a memristor, a RRAM element, a memcapacitor, a phase change material (PCM) device, a magnetic tunnel junction (MTJ), a programmable resistor, a non-volatile switch, a floating gate MOSFET.

44. A method of performing a data read and/or a data write operation using a memory device, wherein the memory device comprises voltage divider circuitry comprising at least one memory element, wherein the at least one memory element is operable or selected to be in a resistance and/or impedance state representative of at least part of the data, providing a memory device voltage divider circuitry, wherein the at least one memory element is capacitive and is connected to one or more further capacitive elements such that the voltage divider circuitry comprises a capacitor divider arrangement;
wherein the method comprises dividing a voltage applied to the voltage divider circuitry in dependence on the resistance and/or impedance as part of a data read and/or data write operation.

45. A memory system comprising a plurality of memory cells, wherein each memory cell comprises:
voltage divider circuitry comprising at least one memory element, wherein the at least one memory element is operable or selected to be in a resistance and/or impedance state representative of at least part of the data;
wherein the voltage divider circuitry is configured to divide a voltage in dependence on the resistance and/or impedance state of the at least one memory element as part of a data read and/or a data write operation, wherein the at least one memory element is capacitive and is connected to one or more further capacitive elements such that the voltage divider circuitry comprises a capacitor divider arrangement; and
one or more common readout and/or write lines for one or more groups of the plurality of memory cells.
